(19) United States
(12) Patent Application Publication
(10) Pub. No.: US 2025/0145452 A1
(43) Pub. Date: May 8, 2025

(54) MICRO-ELECTRO-MECHANICAL SYSTEM PACKAGE AND FABRICATION METHOD THEREOF

(71) Applicant: Vanguard International Semiconductor Corporation, Hsinchu (TW)

(72) Inventors: RAKESH CHAND, Singapore (SG); RAMACHANDRAMURTHY PRADEEP YELEHANKA, Singapore (SG); GUOFU ZHOU, Singapore (SG); HUP FONG TAN, Singapore (SG); ROHIT PULIKKAL KIZHAKKEYIL, Singapore (SG); Sock Kuan Soo, Singapore (SG)

(73) Assignee: Vanguard International Semiconductor Corporation, Hsinchu (TW)

(21) Appl. No.: 18/504,160

(22) Filed: Nov. 8, 2023

(51) Int. Cl. B81B 7/00; B81C 1/00

(52) U.S. Cl. CPC B81B 7/0038; B81C 1/00285; B81B 2201/0235; B81B 2201/0242; B81B 2203/0315; B81B 2207/07; B81C 2203/0172

(57) ABSTRACT

A MEMS package includes an interconnect structure disposed on a wafer. A first device substrate including a first MEMS device and a second device substrate including a second MEMS device are laterally separated from each other, disposed on the wafer and bonded to the interconnect structure. A first cap substrate with a first cavity is bonded to the first device substrate. A second cap substrate with a second cavity is bonded to the second device substrate. A getter is disposed on the interconnect structure and directly under the second MEMS device. The first cavity has a first pressure, and the second cavity has a second pressure lower than the first pressure.

### BACKGROUND OF THE INVENTION

### 1. Field of the Invention

The present disclosure relates generally to micro-electro-mechanical system (MEMS) packages, and more particularly to a MEMS package including MEMS devices with different pressures in respective cavities, and fabrication methods thereof.

### 2. Description of the Prior Art

Micro-electro-mechanical system devices are (MEMS) microscopic devices that integrate mechanical and electrical components to sense physical quantities and/or to interact with the surrounding environment. MEMS devices, such as accelerometers, gyroscopes, pressure sensors and microphones, have found widespread use in many modern electronic products. For example, inertial measurement units (IMU) composed of accelerometers and/or gyroscopes are commonly used in tablet computers, automobiles, or smartphones. For some applications, various MEMS devices need to be integrated into one MEMS package. However, for MEMS devices requiring different pressures, these MEMS devices need to be fabricated separately at different ambient pressure and then co-packaged. Therefore, the whole fabricating process of the conventional MEMS packages is complicated and the conventional MEMS packages have large footprint.

### SUMMARY OF THE INVENTION

In view of this, the present disclosure provides micro-electro-mechanical system (MEMS) packages and fabrication methods thereof to overcome the drawbacks of the conventional MEMS packages. The MEMS package of the present disclosure includes a getter disposed on an interconnect structure formed on a wafer and directly under a MEMS device requiring a relatively high vacuum, thereby reducing the pressure in a cavity directly above the MEMS device. The MEMS package includes MEMS devices with different pressures in respective cavities, and the MEMS devices with different pressures are fabricated and packaged simultaneously on the same wafer. Therefore, the whole fabricating process of the MEMS package is simplified and the footprint of the MEMS package is small compared with those of the conventional MEMS packages.

According to one embodiment of the present disclosure, a MEMS package is provided and includes a wafer, an interconnect structure, a passivation layer, a first device substrate, a second device substrate, a first cap substrate, a second cap substrate and a getter. The interconnect structure is disposed on the wafer, and the passivation layer is disposed on the interconnect structure. The first device substrate including a first MEMS device is disposed on the wafer and bonded to the interconnect structure. The second device substrate including a second MEMS device is laterally spaced apart from the first device substrate, disposed on the wafer and bonded to the interconnect structure. The first cap substrate with a first cavity is bonded to the first device substrate. The second cap substrate with a second cavity is bonded to the second device substrate. The getter is disposed on the interconnect structure, in an opening of the passivation layer and directly under the second MEMS device. In addition, the first cavity has a first pressure, and the second cavity has a second pressure lower than the first pressure.

According to one embodiment of the present disclosure, a method of fabricating a MEMS package is provided and includes the following steps. A cap wafer with a first cavity and a second cavity formed therein is provided. A device wafer is provided and bonded to the cap wafer. The device wafer is patterned to form a first MEMS device and a second MEMS device laterally spaced apart from each other, where the first cavity corresponds to the first MEMS device, and the second cavity corresponds to the second MEMS device. A wafer with an interconnect structure formed thereon is provided. A getter is formed on the interconnect structure. The device wafer is bonded to the interconnect structure on the wafer at a first pressure, where both the first cavity and the second cavity have the first pressure, and the getter is located directly under the second MEMS device. In addition, the getter is activated to reduce the first pressure in the second cavity to a second pressure, where the first cavity has the first pressure, and the second cavity has the second pressure lower than the first pressure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a MEMS package according to one embodiment of the present disclosure.

FIG. 2 is a schematic cross-sectional view of a MEMS package according to another embodiment of the present disclosure.

FIG. 3 is a schematic cross-sectional view of a MEMS package according to further another embodiment of the present disclosure.

FIG. 4, FIG. 5, FIG. 6, FIG. 7 and FIG. 8 are schematic cross-sectional views of some stages of a method of fabricating a MEMS package according to one embodiment of the present disclosure.

FIG. 9 and FIG. 10 are schematic cross-sectional views of some stages of forming a getter on an interconnect structure formed on a wafer according to another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first”, “second”, and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS packages and fabrication methods thereof. The MEMS package includes different MEMS devices with different pressures in respective cavities, and these MEMS devices are fabricated and packaged simultaneously on the same wafer. In the MEMS package, a getter is disposed on an interconnect structure of a wafer and directly under a MEMS device requiring a relatively high vacuum, thereby reducing the pressure in a cavity directly above the MEMS device. In some embodiments, the MEMS package includes an inertial measurement unit (IMU) including of an accelerometer with a low vacuum or atmospheric pressure, and a gyroscope with a high vacuum. The whole fabricating process of the MEMS packages of the present disclosure is simplified and the footprint of the MEMS packages is smaller compared with those of the conventional MEMS packages.

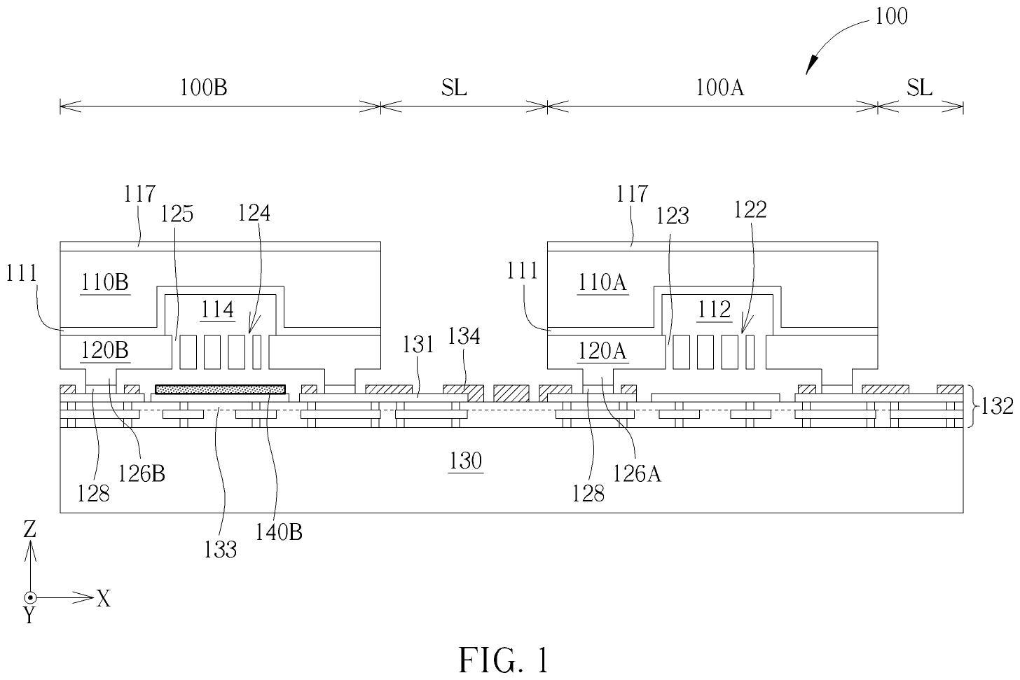

FIG. 1 is a schematic cross-sectional view of a MEMS package 100 according to one embodiment of the present disclosure. The MEMS package 100 includes various MEMS devices laterally separated from each other and packaged on the same wafer. In some embodiments, the MEMS package 100 includes a first device substrate 120A including a first MEMS device 122 and located in a first MEMS region 100A, and a second device substrate 120B including a second MEMS device 124 and located in a second MEMS region 100B. The first MEMS region 100A and the second MEMS region 100B are separated by a scribe line SL, and the first device substrate 120A and the second device substrate 120B are laterally separated from each other. The first device substrate 120A and the second device substrate 120B are disposed on the same wafer 130 and bonded to an interconnect structure 132 formed on the wafer 130. The wafer 130 may include multiple complementary metal oxide semiconductor (CMOS) transistors or other elements formed therein. The interconnect structure 132 includes several metal layers, several inter-metal dielectric (IMD) layers and several vias in the IMD layers to connect two metal layers. The metal layers includes a top electrode layer 131, and the IMD layers includes a top dielectric layer 133 disposed under the top electrode layer 131. In addition, a passivation layer 134 is disposed on the interconnect structure 132 and has multiple openings to expose pads, bond areas, and some portions of the top electrode layer 131 or the top dielectric layer 133 of the interconnect structure 132, respectively.

In the MEMS package 100, the first MEMS device 122 and the second MEMS device 124 require different vacuum levels. The MEMS structures of the first MEMS device 122 and the second MEMS device 124 are different from each other. Each of the first MEMS device 122 and the second MEMS device 124 may include features such as standoff bumps, trenches, proof masses, etc., and the layout of these features in the first MEMS device 122 is different from that in the second MEMS device 124. In order to make the figure simple and easy to understand, the MEMS structures of the first MEMS device 122 and the second MEMS device 124 are simplified in FIG. 1. For example, the first MEMS device 122 includes multiple trenches 123, and the second MEMS device 124 includes multiple trenches 125, where the layout of the trenches 123 is different from the layout of the trenches 125. In some embodiments, the first MEMS device 122 may be an accelerometer requiring low vacuum or atmospheric pressure, and the second MEMS device 124 may be a gyroscope requiring high vacuum, but not limited thereto.

Moreover, a first bond seal ring 126A is disposed on the bottom surface of the first device substrate 120A, and a second bond seal ring 126B is disposed on the bottom surface the second device substrate 120B. The first bond seal ring 126A and the second bond seal ring 126B are bonded to the interconnect structure 132 through a bonding material 128, thereby bonding the first device substrate 120A and the second device substrate 120B with the wafer 130. In some embodiments, the first bond seal ring 126A and the first device substrate 120A may be an integral structure and have the same composition such as silicon. The second bond seal ring 126B and the second device substrate 120B may also be an integral structure and have the same composition such as silicon. The composition of the bonding material 128 is for example germanium (Ge) for eutectic bonding with the top electrode layer 131 of the interconnect structure 132. The first bond seal ring 126A, the second bond seal ring 126B and the bonding material 128 are disposed in the bond areas of the interconnect structure 132.

In addition, the MEMS package 100 includes a first cap substrate 110A with a first cavity 112 located directly above the first MEMS device 122, and a second cap substrate 110B with a second cavity 114 located directly above the second MEMS device 124. The first cap substrate 110A and the second cap substrate 110B may have the same composition such as silicon. The first cap substrate 110A is bonded to the first device substrate 120A through a bonding layer 111. The second cap substrate 110B is bonded to the second device substrate 120B through another bonding layer 111. The bonding layer 111 is disposed between the first device substrate 120A and the first cap substrate 110A. The bonding layer 111 is also disposed between the second device substrate 120B and the second cap substrate 110B. In some embodiments, the bonding layer 111 is further extended into the first cavity 112 and the second cavity 114 to be conformally disposed on the sidewalls and the bottom surfaces of the first cavity 112 and the second cavity 114. The composition of the bonding layer 111 may be silicon oxide. In some embodiments, a conductive layer 117 may be disposed on surfaces of the first cap substrate 110A and the second cap substrate 110B. The conductive layer 117 may be a patterned conductive layer electrically coupled to the first MEMS device 122, the second MEMS device 124 and the interconnect structure 132. The composition of the conductive layer 117 may be aluminum (Al).

In some embodiments, the MEMS package 100 includes a getter 140B disposed on the interconnect structure 132 and directly under the second MEMS device 124. The getter 140B is activated to absorb gases such as H₂, N₂, CO, CO₂ or H₂O in the second cavity 114, thereby reducing the pressure in the second cavity 114. As a result, the first cavity 112 has a first pressure P1, and the second cavity 114 has a second pressure P2 lower than the first pressure P1. For example, the first pressure P1 is a low vacuum or atmospheric pressure required for the first MEMS device 122 such as an accelerometer, and the second pressure P2 is a high vacuum required for the second MEMS device 124 such as a gyroscope. The getter 140B is activated by a thermal process while the first device substrate 120A and the second device substrate 120B are bonded to the interconnect structure 132. The getter 140B may be activated at about 150° C. to about 450° C. In some embodiments, the composition of the getter 140B may be Ti, a Ti based alloy, a Zr based alloy, a Zr-V based alloy, a Zr-Co based alloy or other suitable material for absorbing gases in a cavity of the MEMS package. The Ti based alloy is for example Ti-Zr, Ti-Mo or Ti-Zr-V. The Zr based alloy is for example Zr-Al, Zr-C or Zr-Fe. The Zr-V based alloy is for example Zr-V-Fe or Zr-V-Mn. The Zr-Co based alloy is for example Zr-Co, Zr-Co-Ce or Zr-Co-La. The getter 140B may be a thin film with a thickness of about 1 μm to about 10 μm, or the getter 140B may be a thick film with a thickness of about 10 μm to about 1000 μm. Moreover, the getter 140B may have a pattern corresponding to the layout of the trenches 125 of the second MEMS device 124.

In one embodiment, the getter 140B is disposed in an opening of the passivation layer 134 and in contact with the top surface of the top electrode layer 131. The getter 140B is electrically connected to the interconnect structure 132 through the top electrode layer 131. In another embodiment, the getter 140B is disposed on the same level with the top electrode layer 131 and in contact with the top surface of the top dielectric layer 133. The getter 140B is electrically connected to the interconnect structure 132 through the vias in the top dielectric layer 133 or some portions of the top electrode layer 131 connected to the getter 140B. In some embodiments, the getter 140B is configured as a conductive stopper for the second MEMS device 124. The location of the getter 140B may correspond to the proof masses of the second MEMS device 124. Moreover, the vertical projection area of the getter 140B is overlapped with the vertical projection area of the second cavity 114. In some embodiments, the vertical projection area of the getter 140B is greater than or the same as the vertical projection area of the second cavity 114, thereby efficiently absorbing the gases in the second cavity 114 to provide a high vacuum for the second MEMS device 124. In other embodiments, the vertical projection area of the getter 140B may be smaller than the vertical projection area of the second cavity 114 while the second MEMS device 124 requires a medium vacuum.

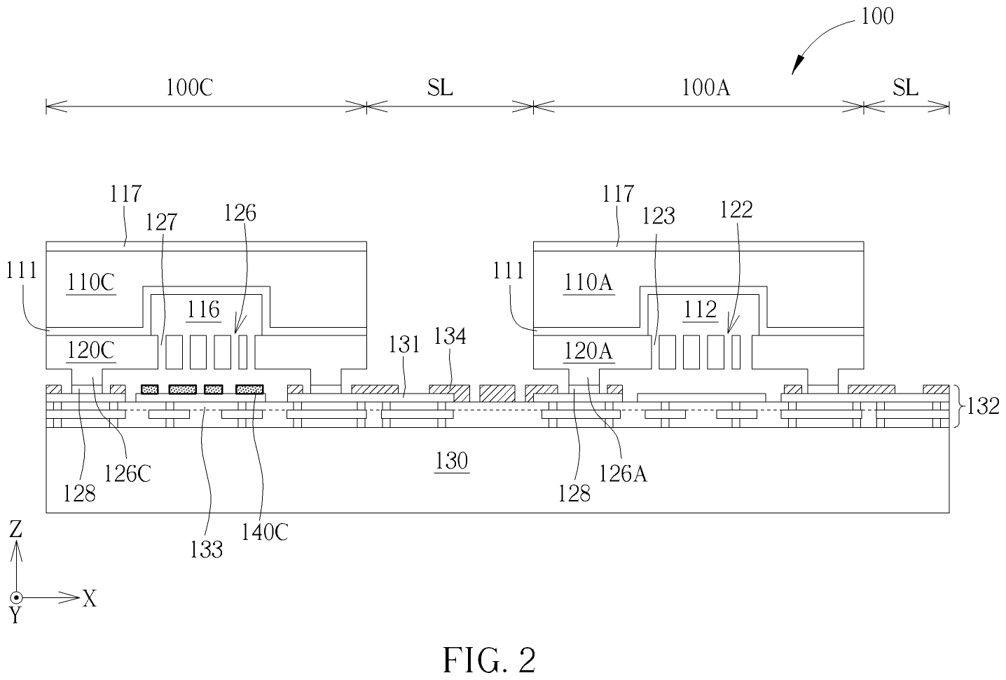

FIG. 2 is a schematic cross-sectional view of a MEMS package 100 according to another embodiment of the present disclosure. The MEMS package 100 of FIG. 2 includes a third device substrate 120C including a third MEMS device 126 and located in a third MEMS region 100C. The first MEMS region 100A and the third MEMS region 100C are separated by the scribe line SL. The details of the features in the first MEMS region 100A may refer to the aforementioned description of FIG. 1, and not repeated herein. The third device substrate 120C is also disposed on the same wafer 130 and bonded to the interconnect structure 132. The third MEMS device 126 requires a vacuum level different from that of the first MEMS device 122. The MEMS structure of the third MEMS device 126 is different from that of the first MEMS device 122. The third MEMS device 126 may include features such as standoff bumps, trenches, proof masses, etc., and the layout of these features in the third MEMS device 126 is different from that in the first MEMS device 122. In order to make the figure simple and easy to understand, the MEMS structures of the first MEMS device 122 and the third MEMS device 126 are simplified in FIG. 2. For example, the third MEMS device 126 includes multiple trenches 127, and the layout of the trenches 126 is different from the layout of the trenches 123 in the first MEMS device 122. In some embodiments, the third MEMS device 126 may be a gyroscope requiring high vacuum or medium vacuum, or an accelerometer requiring medium vacuum.

Moreover, a third bond seal ring 126C is disposed on the bottom surface of the third device substrate 120C. The third bond seal ring 126C is also bonded to the interconnect structure 132 through the bonding material 128. The third bond seal ring 126C and the third device substrate 120C may be an integral structure and have the same composition such as silicon. In addition, the MEMS package 100 includes a third cap substrate 110C with a third cavity 116 directly above the third MEMS device 126. The composition of the third cap substrate 110C may be silicon. The third cap substrate 110C is bonded to the third device substrate 120C through the bonding layer 111. The bonding layer 111 is disposed between the third device substrate 120C and the third cap substrate 110C. Moreover, the bonding layer 111 may be further extended into the third cavity 116 to be conformally disposed on the sidewalls and the bottom surface of the third cavity 116. Furthermore, the conductive layer 117 may be also disposed on the surface of the third cap substrate 110C. The conductive layer 117 may be a patterned conductive layer electrically coupled to the third MEMS device 126.

As shown in FIG. 2, in one embodiment, the MEMS package 100 includes a getter 140C disposed on the interconnect structure 132 and directly under the third MEMS device 126. The getter 140C is activated to absorb gases in the third cavity 116, thereby reducing the pressure in the third cavity 116. The getter 140C may have a pattern corresponding to the trenches 127 of the third MEMS device 126, thereby efficiently absorbing gases in the third cavity 116 through the trenches 127 with a small area of the getter 140C. As a result, the third cavity 116 has a third pressure P3 lower than the first pressure P1 of the first cavity 112. For example, the third pressure P3 is a medium vacuum required for the third MEMS device 126 such as a gyroscope or an accelerometer. The getter 140C is activated by a thermal process while the first device substrate 120A and the third device substrate 120C are bonded to the interconnect structure 132. The getter 140C may be activated at about 150° C. to about 450° C. In some embodiments, the composition of the getter 140C includes Ti, a Ti based alloy, a Zr based alloy, a Zr-V based alloy, a Zr-Co based alloy or other suitable material for absorbing gases in a cavity of the MEMS package.

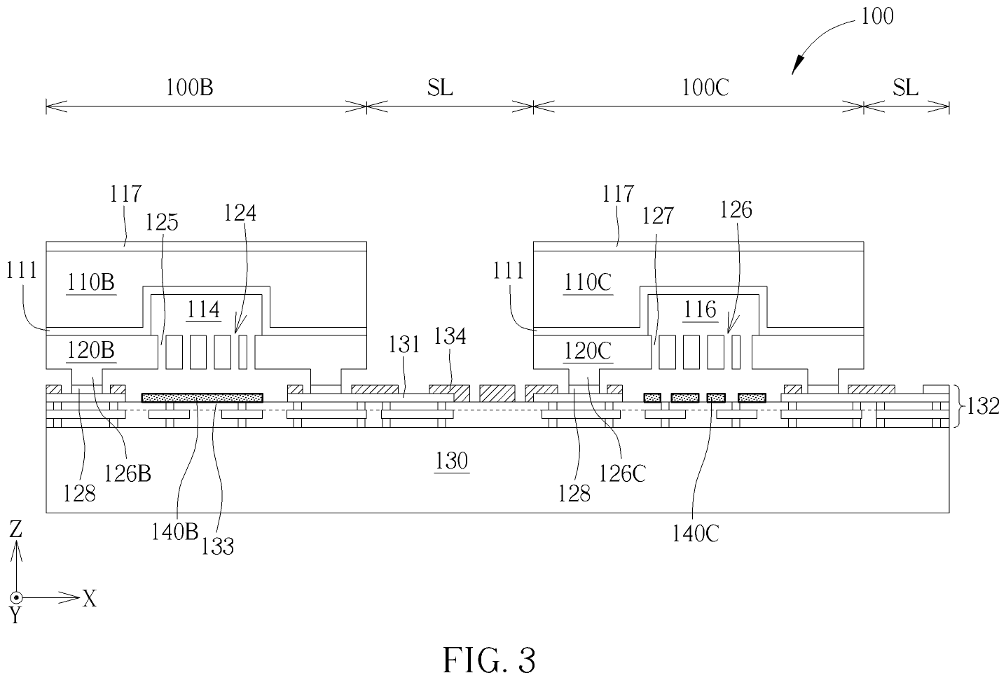

FIG. 3 is a schematic cross-sectional view of a MEMS package 100 according to further another embodiment of the present disclosure. The MEMS package 100 of FIG. 3 includes the second MEMS region 100B and the third MEMS region 100C separated by the scribe line SL. The details of the features in the second MEMS region 100B and the third MEMS region 100C may refer to the aforementioned descriptions of FIG. 1 and FIG. 2, and not repeated herein. The getter 140B directly under the second MEMS device 124 provides the second pressure P2 in the second cavity 114. The getter 140C directly under the third MEMS device 126 provides the third pressure P3 in the third cavity 116. The third pressure P3 is different from the second pressure P2. For example, the second MEMS device 124 may be a gyroscope requiring high vacuum, and the third MEMS device 126 may be a gyroscope or an accelerometer requiring medium vacuum.

In some other embodiments, the MEMS package 100 may include the first MEMS region 100A, the second MEMS region 100B and the third

MEMS region 100C separated from each other by the scribe lines SL. The first cavity 112 directly above the first MEMS device 122 has the first pressure P1. The second cavity 114 directly above the second MEMS device 124 has the second pressure P2. The third cavity 116 directly above the third MEMS device 126 has the third pressure P3. The third pressure P3 is different from the second pressure P2 and is lower than the first pressure P1. According to the embodiments of the present disclosure, the MEMS package includes different MEMS devices with different pressures in respective cavities and packaged simultaneously on the same wafer through the getters.

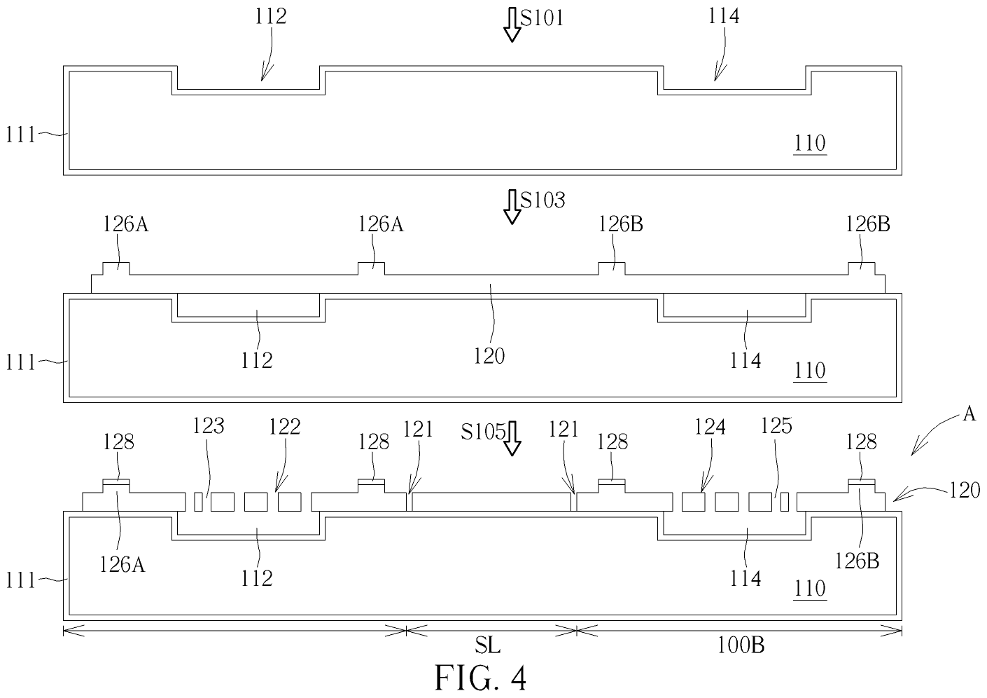

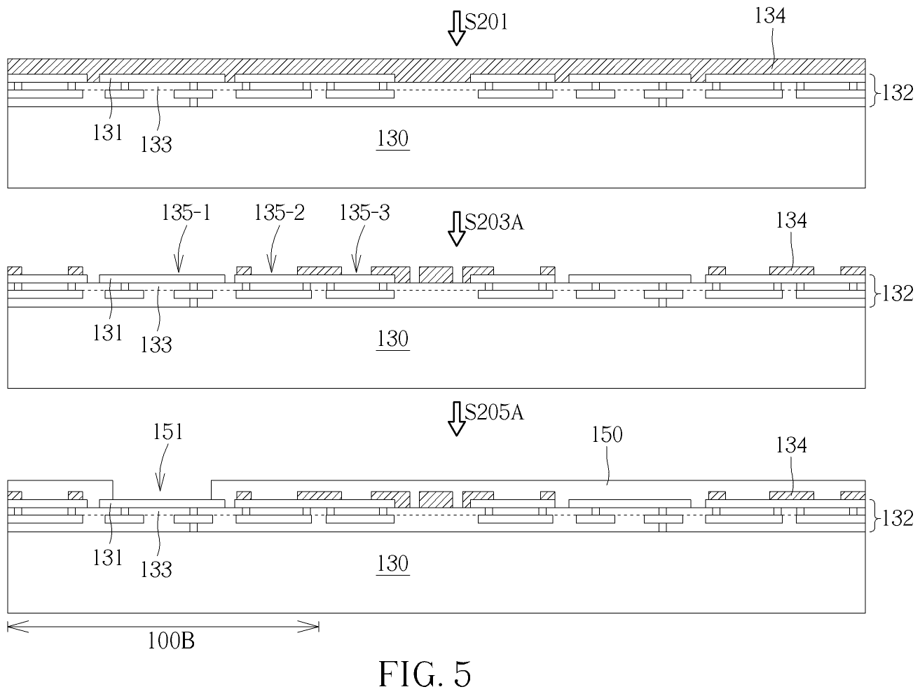

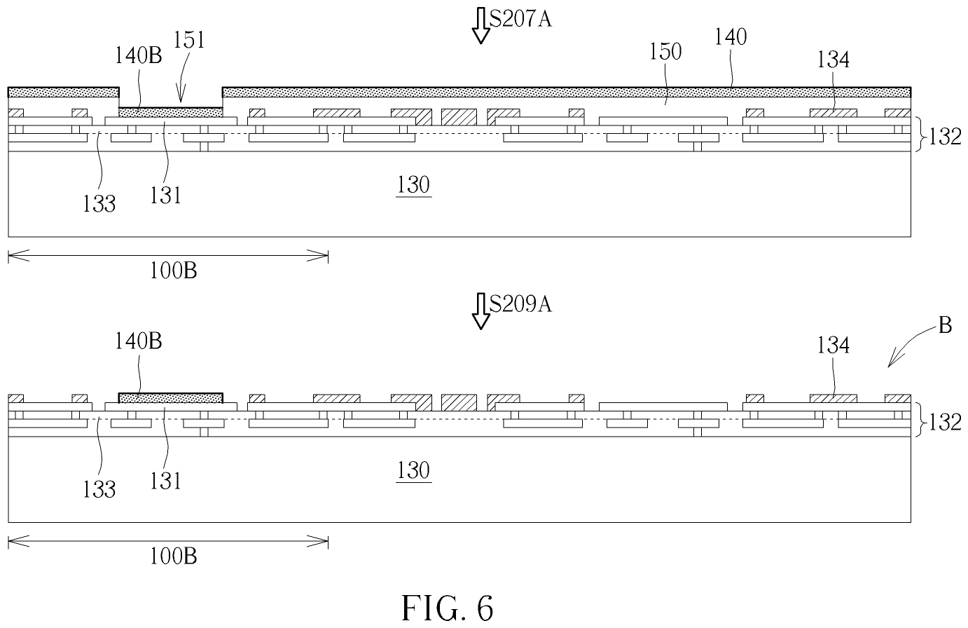

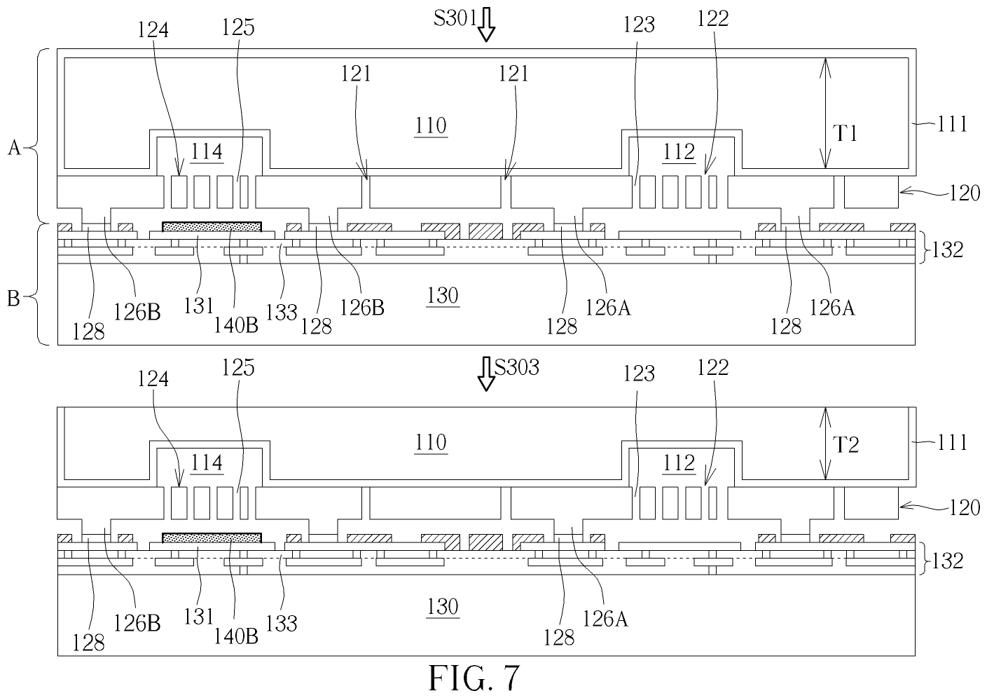

FIG. 4, FIG. 5, FIG. 6, FIG. 7 and FIG. 8 are schematic cross-sectional views of some stages of a method of fabricating a MEMS package 100 according to one embodiment of the present disclosure. Referring to FIG. 4, in step S101, firstly, a cap wafer 110 such as a silicon wafer is provided. A first cavity 112 and a second cavity 114 are formed by an etching process on a surface of the cap wafer 110. Then, a bonding layer 111 is conformally formed on the cap wafer 110 and in the first cavity 112 and the second cavity 114 to wrap around the cap wafer 110. The composition of the bonding layer 111 is, for example, silicon oxide. The bonding layer 111 may be formed by a thermal oxidation process or a deposition process.

Next, still referring to FIG. 4, in step S103, a device wafer 120 such as a silicon wafer is provided and bonded with the cap wafer 110 by fusion bonding to cover the first cavity 112 and the second cavity 114. Thereafter, the device wafer 120 is thinned by grinding or etching, and then patterned by photolithography and etching processes to form a first bond seal ring 126A, a second bond seal ring 126B and standoff bumps (not shown) on a surface of the device wafer 120. Afterwards, still referring to FIG. 4, in step S105, a bonding material 128 such as Ge is formed on the first bond seal ring 126A and the second bond seal ring 126B by deposition and patterning processes. Then, the device wafer 120 is patterned by photolithography and etching processes to simultaneously form a first MEMS device 122 and a second MEMS device 124 laterally spaced apart from each other. The first MEMS device 122 is directly above the first cavity 112, and the second MEMS device 124 is directly above the second cavity 114. The first MEMS device 122 includes multiple trenches 123 connected to the first cavity 112, and the second MEMS device 124 includes multiple trenches 125 connected to the second cavity 114. Moreover, pre-cut lines 121 are formed in a scribe line SL between a first MEMS region 100A and a second MEMS region 100B by patterning the device wafer 120. As a result, a structure A is obtained in the step S105, where the device wafer 120 includes the first MEMS device 122 and the second MEMS device 124 and is bonded with the cap wafer 110 having the first cavity 112 and the second cavity 114 formed therein.

Referring to FIG. 5, in step S201, a wafer 130 such as a CMOS wafer with an interconnect structure 132 formed thereon is provided. The interconnect structure 132 includes multiple metal layers, multiple IMD layers and multiple vias in the IMD layers to connect two metal layers. The metal layers includes a top electrode layer 131, and the IMD layers includes a top dielectric layer 133 disposed under the top electrode layer 131. Moreover, a passivation layer 134 is deposited on the interconnect structure 132. The composition of the passivation layer 134 is for example silicon oxide, silicon nitride, silicon oxynitride or a combination thereof.

Next, still referring to FIG. 5, in step S203A, the passivation layer 134 is patterned by photolithography and etching processes to form multiple openings 135-1, 135-2 and 135-3. In one embodiment, a portion of the top electrode layer 131 is exposed by the opening 135-1 for forming a getter thereon. In another embodiment, a portion of the top dielectric layer 133 is exposed by the opening 135-1 for forming a getter thereon. A bond area of the interconnect structure 132 is exposed by the opening 135-2 for bonding with the first bond seal ring 126A and the second bond seal ring 126B. A pad of the interconnect structure 132 is exposed by the opening 135-3.

Thereafter, still referring to FIG. 5, in step S205A, a patterned sacrificial layer 150 is formed on the passivation layer 134. In one embodiment, the patterned sacrificial layer 150 may be a patterned photoresist formed by photolithography. In another embodiment, the patterned sacrificial layer 150 may be formed by photolithography and etching processes. The composition of the patterned sacrificial layer 150 may be dielectric materials with etching selectivity to the passivation layer 134. The patterned sacrificial layer 150 has an opening 151 to expose a portion of the interconnect structure 132 and covers the openings 135-2 and 135-3 of the passivation layer 134. The opening 151 corresponds to the opening 135-1 of the passivation layer 134. In some embodiments, a portion of the top electrode layer 131 or a portion of the top dielectric layer 133 is exposed by the opening 151 for forming a getter thereon.

Next, referring to FIG. 6, in step S207A, a getter material layer 140 is deposited on the patterned sacrificial layer 150 and in the opening 151. A portion of the getter material layer 140 in the opening 151 is deposited on the interconnect structure 132 to form a getter 140B. The composition of the getter material layer 140 may be Ti, a Ti based alloy, a Zr based alloy, a Zr-V based alloy, a Zr-Co based alloy or other suitable getter material. The getter material layer 140 is for example Ti-Zr, Ti-Mo, Ti-Zr-V, Zr-Al, Zr-C, Zr-Fe, Zr-V-Fe, Zr-V-Mn, Zr-Co, Zr-Co-Ce or Zr-Co-La, but not limited thereto. The thickness of the getter material layer 140 may be from about 1 μm to about 1000 μm. Then, still referring to FIG. 6, in step S209A, the patterned sacrificial layer 150 is stripped by soaking or etching process to remove the getter material layer 140 deposited thereon together, thereby remaining the getter 140B on the interconnect structure 132. The getter 140B is in contact with the top electrode layer 131 or the top dielectric layer 133. Moreover, the getter 140B is electrically connected to the interconnect structure 132. The vertical projection area of the getter 140B may be the same as that of the second cavity 114. When viewed from a top, the shape of the getter 140B is the same as that of the opening 151. In some embodiments, the patterned sacrificial layer 150 may have multiple openings corresponds to the trenches 125 of the second MEMS device 124, so that the getter 140C as shown in FIG. 2 is formed with a pattern corresponding to the trenches 125 of the second MEMS device 124. As a result, a structure B is obtained in the step S209A, where the getter 140B or the getter 140C is formed on the interconnect structure 132 that is formed on the wafer 130. In this embodiment, the getter 140B or the getter 140C is formed by using a lift-off process.

Next, referring to FIG. 7, in step S301, the structure A obtained in the step S105 of FIG. 4 is turned upside down and bonded with the structure B obtained in the step S209A of FIG. 6. The device wafer 120 is bonded to the interconnect structure 132 on the wafer 130 at a first pressure P1, so that firstly, both the first cavity 112 and the second cavity 114 have the first pressure P1. The bonding material 128 on the first bond seal ring 126A and the second bond seal ring 126B is bonded to the bond area of the interconnect structure 132 by eutectic bonding. The getter 140B located directly under the second MEMS device 124 is activated by a thermal process to absorb gases in the second cavity 114, thereby reducing the first pressure P1 in the second cavity 114 to a second pressure P2. Meanwhile, the pressure in the first cavity 112 is maintained at the first pressure P1. As a result, the first cavity 112 has the first pressure P1, and the second cavity 114 has the second pressure P2 lower than the first pressure P1. The getter 140B may be activated at about 150° C. to about 450° C., which is depended on the material of the getter 140B. In some embodiments, the activation temperature of the getter 140B is lower than the temperature of the bonding process for the device wafer 120 and the wafer 130, and the getter 140B is activated during the bonding process. In some other embodiments, the activation temperature of the getter 140B is higher than the temperature of the bonding process for the device wafer 120 and the wafer 130, and the getter 140B is activated by a thermal process after the bonding process.

In the step S301, the cap wafer 110 has a thickness T1, and the bonding layer 111 is conformally formed on the cap wafer 110 and in the first cavity 112 and the second cavity 114 to wrap around the cap wafer 110. Then, still referring to FIG. 7, in step S303, the cap wafer 110 is thinned by backside grinding or dry etching. The bonding layer 111 on the backside of the cap wafer 110 is also removed, and the cap wafer 110 is thinned from the thickness T1 to a thickness T2.

Thereafter, referring to FIG. 8, in step S305, a conductive layer 117 such as aluminum layer is deposited on the backside of the cap wafer 110 and then patterned by photolithography and etching processes. Next, still referring to FIG. 8, in step S307, a portion of the cap wafer 110 and a portion of the device wafer 120 at the scribe line SL are removed by a sawing process to expose the pads on the interconnect structure 132. As a result, a first cap substrate 110A with the first cavity 112 and a second cap substrate 110B with the second cavity 114 are formed and separated from each other. Also, a first device substrate 120A with the first MEMS device 122 and a second device substrate 120B with the second MEMS device 124 are formed and separated from each other. The first device substrate 120A and the second device substrate 120B are packaged simultaneously on the same wafer 130. The MEMS package 100 of FIG. 1 is completed, where the first cavity 112 directly above the first MEMS device 122 has the first pressure P1, and the second cavity 114 directly above the second MEMS device 124 has the second pressure P2 that is lower than the first pressure P1.

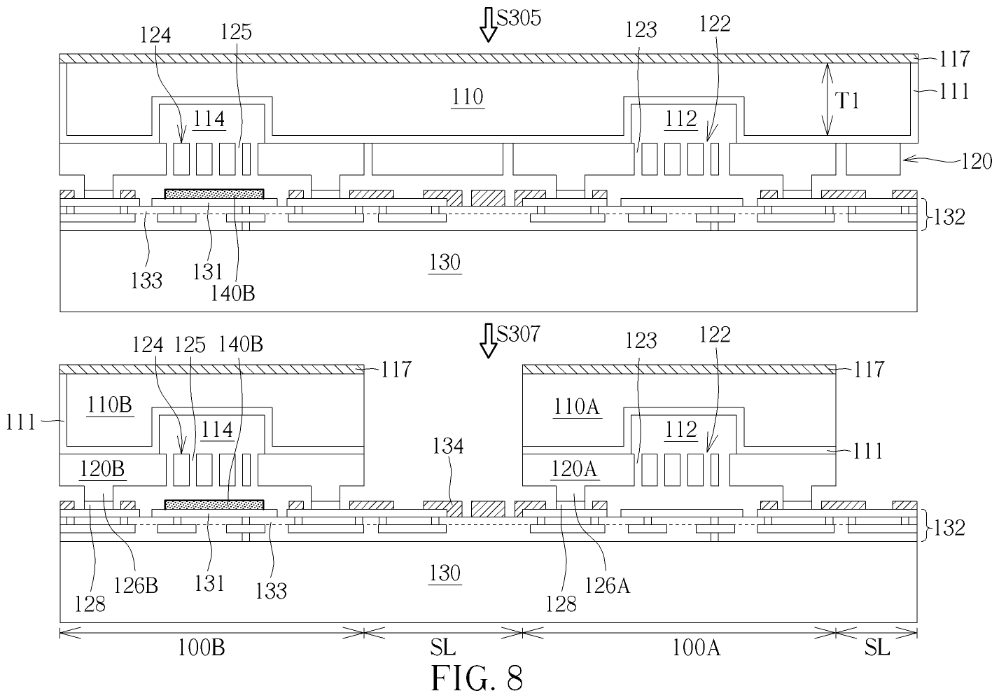

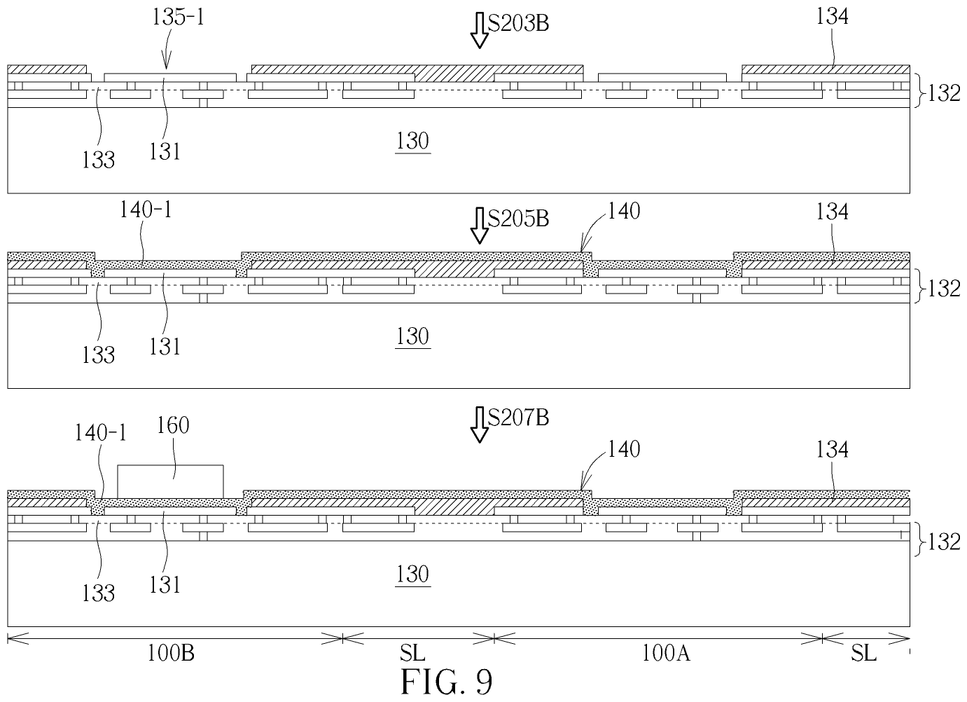

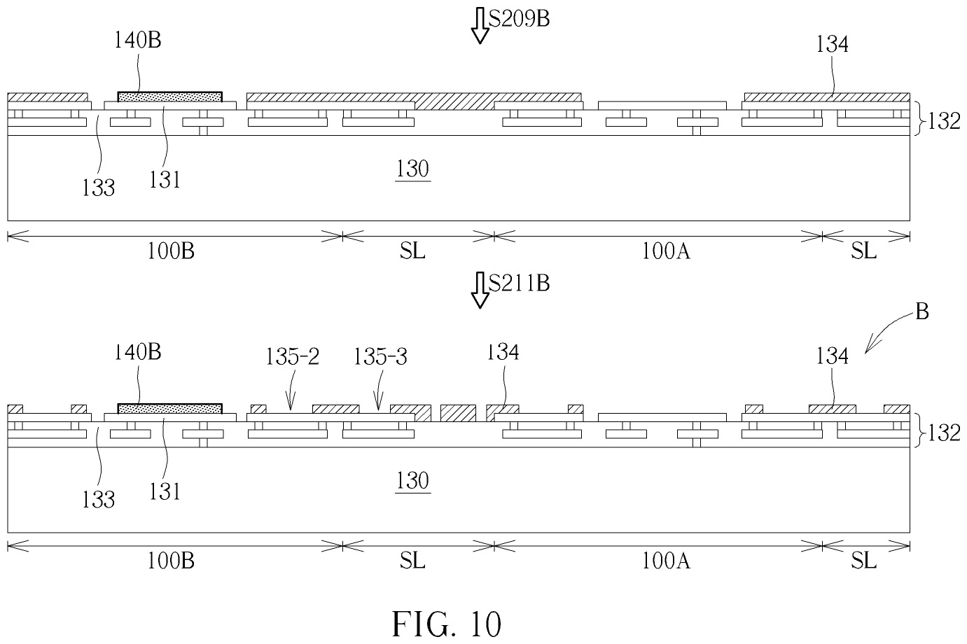

FIG. 9 and FIG. 10 are schematic cross-sectional views of some stages of forming a getter 140B on an interconnect structure 132 formed on a wafer 130 according to another embodiment of the present disclosure. After the step S201 of FIG. 5, referring to FIG. 9, in step S203B, the passivation layer 134 is patterned by photolithography and a first etching process to form an opening 135-1 to expose a portion of the interconnect structure 132. In one embodiment, a portion of the top electrode layer 131 is exposed by the opening 135-1 for forming a getter thereon. In another embodiment, a portion of the top dielectric layer 133 is exposed by the opening 135-1 for forming a getter thereon.

Next, still referring to FIG. 9, in step S205B, a getter material layer 140 is deposited on the passivation layer 134, and a portion 140-1 of the getter material layer 140 is deposited in the opening 135-1 and on the interconnect structure 132. The composition and the thickness of the getter material layer 140 may refer to the aforementioned description of the step S207A in FIG. 6, and not repeated herein. Then, still referring to FIG. 9, in step S207B, a patterned photoresist 160 is formed on the portion 140-1 of the getter material layer 140 in the second MEMS region 100B.

Thereafter, referring to FIG. 10, in step S209B, the getter material layer 140 is etched by using the patterned photoresist 160 as an etch mask. The portion 140-1 of the getter material layer 140 is patterned to form a getter 140B on the interconnect structure 132 in the second MEMS region 100B. The getter 140B is formed to contact with the top electrode layer 131 or the top dielectric layer 133. Moreover, the getter s electrically connected to the interconnect structure 132. The vertical projection area of the getter 140B may be the same as that of the second cavity 114. When viewed from a top, the shape of the getter 140B is the same as that of the patterned photoresist 160. In some embodiments, the patterned photoresist 160 has multiple openings, and the pattern of the patterned photoresist 160 corresponds to the trenches 125 of the second MEMS device 124, so that the getter 140C as shown in FIG. 2 is formed with a pattern corresponding to the trenches 125 of the second MEMS device 124. In this embodiment, the getter 140B or the getter 140C is formed on the interconnect structure 132 by using a dry etching process.

Next, still referring to FIG. 10, in step S211B, the passivation layer 134 is patterned by photolithography and a second etching process to form further openings 135-2 and 135-3 to expose a pad and a bond area of the interconnect structure 132. As a result, a structure B is obtained in the step S211B, where the getter 140B or the getter 140C is formed on the interconnect structure 132 that is formed on the wafer 130.

In some embodiments, the MEMS package 100 of FIG. 1 is completed by the step S101 to the step S105 of FIG. 4, the step S201 of FIG. 5, the step S203B to the step S211B of FIG. 9 and FIG. 10, and the step S301 to the step S307 of FIG. 7 and FIG. 8. In addition, all the MEMS packages 100 of FIG. 2 and FIG. 3, and the MEMS package including the first MEMS region 100A, the second MEMS region 100B and the third MEMS region 100C may be fabricated by using the aforementioned steps of FIG. 4 to FIG. 10.

According to the embodiments of the present disclosure, the MEMS package includes different MEMS devices with different pressures in respective cavities, and these MEMS devices are fabricated and packaged simultaneously on the same wafer. Therefore, the whole fabricating process of the MEMS packages of the present disclosure is simplified and the footprint of the MEMS packages is smaller compared with those of the conventional MEMS packages. The MEMS packages of the present disclosure do not require individual wire bonding, thereby reducing the parasitic effect.

In addition, the MEMS package includes the getter disposed on the interconnect structure formed on the CMOS wafer and directly under the MEMS device requiring high vacuum. The getter is activated to reduce the pressure in the cavity directly above the MEMS device requiring high vacuum. The process of forming the getter is compatible with the process of the CMOS wafer fabrication. The activation of the getter is compatible with the bonding process of the MEMS package fabrication. Therefore, the cost and the time of fabricating the MEMS packages are reduced. Moreover, the MEMS packages of the present disclosure are suitable for 1-axis, 2-axis, 3-axis and 6-axis inertial measurement unit (IMU) and MEMS devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) package, comprising:
a wafer;
an interconnect structure, disposed on the wafer;
a passivation layer, disposed on the interconnect structure;
a first device substrate comprising a first MEMS device, disposed on the wafer and bonded to the interconnect structure;
a second device substrate comprising a second MEMS device, laterally spaced apart from the first device substrate, disposed on the wafer and bonded to the interconnect structure;
a first cap substrate with a first cavity, bonded to the first device substrate;
a second cap substrate with a second cavity, bonded to the second device substrate; and
a getter, disposed in an opening of the passivation layer, on the interconnect structure and directly under the second MEMS device,
wherein the first cavity has a first pressure, and the second cavity has a second pressure lower than the first pressure.

2. The MEMS package of claim 1, wherein the first MEMS device comprises an accelerometer and the second MEMS device comprises a gyroscope.

3. The MEMS package of claim 1, wherein the interconnect structure comprises a top electrode layer, the passivation layer is disposed on the top electrode layer, and the getter is in contact with the top electrode layer.

4. The MEMS package of claim 1, wherein the interconnect structure comprises a top dielectric layer disposed under a top electrode layer, and the getter is in contact with the top dielectric layer.

5. The MEMS package of claim 1, wherein the getter is electrically connected to the interconnect structure.

6. The MEMS package of claim 1, wherein a vertical projection area of the getter is overlapped with a vertical projection area of the second cavity.

7. The MEMS package of claim 1, wherein the second MEMS device comprises a plurality of trenches, and the getter has a pattern corresponding to the plurality of trenches of the second MEMS device.

8. The MEMS package of claim 1, wherein the getter comprises Ti, a Ti based alloy, a Zr based alloy, a Zr-V based alloy or a Zr-Co based alloy.

9. The MEMS package of claim 1, wherein the getter is configured to be a conductive stopper for the second MEMS device.

10. The MEMS package of claim 1, further comprising:
a third device substrate comprising a third MEMS device, laterally spaced apart from the first device substrate and the second device substrate, disposed on the wafer and bonded to the interconnect structure;
a third cap substrate with a third cavity, bonded to the third device substrate; and
a further getter, disposed on the interconnect structure and directly under the third MEMS device,
wherein the third cavity has a third pressure different from the second pressure and lower than the first pressure.

11. A method of fabricating a micro-electro-mechanical system (MEMS) package, comprising:
providing a cap wafer with a first cavity and a second cavity formed therein;
providing a device wafer;
bonding the device wafer to the cap wafer;
patterning the device wafer to form a first MEMS device and a second MEMS device laterally spaced apart from each other, wherein the first MEMS device corresponds to the first cavity, and the second MEMS device corresponds to the second cavity;
providing a wafer with an interconnect structure formed thereon;
forming a getter on the interconnect structure;
bonding the device wafer to the interconnect structure on the wafer at a first pressure, wherein both the first cavity and the second cavity have the first pressure, and the getter is located directly under the second MEMS device; and
activating the getter to reduce the first pressure in the second cavity to a second pressure, wherein the first cavity has the first pressure, and the second cavity has the second pressure lower than the first pressure.

12. The method of claim 11, wherein the interconnect structure comprises a top electrode layer formed on a top dielectric layer, and the getter is formed to contact with the top electrode layer or the top dielectric layer.

13. The method of claim 11, wherein the getter is electrically connected to the interconnect structure.

14. The method of claim 11, wherein the getter comprises Ti, a Ti based alloy, a Zr based alloy, a Zr-V based alloy or a Zr-Co based alloy.

15. The method of claim 11, wherein forming the getter comprises:
forming a passivation layer on the interconnect structure;
patterning the passivation layer by an etching process to form an opening to expose a portion of the interconnect structure;
forming a patterned sacrificial layer on the passivation layer to expose the portion of the interconnect structure;
depositing a getter material layer on the patterned sacrificial layer and the portion of the interconnect structure; and
removing the patterned sacrificial layer to form the getter, wherein a vertical projection area of the getter is overlapped with a vertical projection area of the second cavity.

16. The method of claim 15, wherein before depositing the getter material layer, further openings of the passivation layer are formed by the etching process to expose a pad and a bond area of the interconnect structure, and the patterned sacrificial layer covers the further openings of the passivation layer.

17. The method of claim 11, wherein forming the getter comprises:
forming a passivation layer on the interconnect structure;
patterning the passivation layer by a first etching process to form an opening to expose a portion of the interconnect structure;
depositing a getter material layer on the passivation layer and the portion of the interconnect structure; and
patterning the getter material layer to form the getter, wherein a vertical projection area of the getter is overlapped with a vertical projection area of the second cavity.

18. The method of claim 17, wherein after the getter is formed, the passivation layer is patterned by a second etching process to form further openings to expose a pad and a bond area of the interconnect structure.

19. The method of claim 11, wherein forming the getter comprises:
depositing a getter material layer on the interconnect structure; and
patterning the getter material layer to form the getter with a pattern,
wherein the second MEMS device comprises a plurality of trenches, and the pattern of the getter corresponds to the plurality of trenches of the second MEMS device.

20. The method of claim 11, further comprising:
removing a portion of the cap wafer and a portion of the device wafer at a scribe line to form a first cap substrate with the first cavity, a second cap substrate with the second cavity, a first device substrate comprising the first MEMS device, and a second device substrate comprising the second MEMS device.
